(19) United States
(12) Patent Application Publication
(10) Pub. No.: US 2013/0152375 A1
(43) Pub. Date: Jun. 20, 2013

(54) Magnetic Platinum Catalyst and Method of Making and its Application as an Engine Fuel Enhancer

(71) Applicants: Shi Min Chen, Shenzhen (CN); Yong Sheng Chen, Shenzhen (CN)

(72) Inventors: Shi Min Chen, Shenzhen (CN); Yong Sheng Chen, Shenzhen (CN)

(21) Appl. No.: 13/327,438

(22) Filed: Dec. 15, 2011

(51) Int. Cl. B01J 23/63; B01J 23/89; H05K 13/00; B23P 11/00; F02M 27/02; F02M 27/04

(52) U.S. Cl. 29/592.1; 123/538; 29/890; 502/302; 502/5

(57) ABSTRACT

A magnetic platinum catalyst and its application as an engine fuel enhancer. The method of making the magnetic platinum catalyst includes: the use of neodymium magnetic alloy containing 25-50% of the neutral neodymium (NdFeB) alloys, processed into a diameter of 13 mm, a length 9 mm cylinder, as a catalyst carrier. The surface of the catalyst carrier is treated with antioxidant. A platinum group metal is used as the catalyst rare earth materials to produce a catalyst acid soaking solution. The solution includes 0.01-0.2% platinum and 0.01-0.15% rhodium. The pH of the solution is adjusted to 4 using oxalic acid. After soaking in the solution, draining, and drying, the carrier is placed in a muffle furnace and baked. The catalyst is firmly attached to the surface of the carrier to form a magnetic platinum catalyst having catalyzing ability. Such catalyst is used in connection with engine fuel to enhance its operation.

### FIELD OF THE INVENTION

The present invention is directed to the field of metal material technology. In particular, it applies to a physical enhancement catalyst for fuel powered engines. The present invention uses a permanently magnetic platinum catalyst to apply physical enhancement catalysis in fuel powered automobile engines.

### BACKGROUND OF THE INVENTION

Currently, the pollution from the energy consumption and gas waste of engines, especially automobile engines has become one of the major social issues. Simply improving the engine technology, or improving the treatment of the engine gas waste are limited to changing the engine or re-combustion of the high temperature gases (compounds) produced during incomplete combustion of the engine, such as CO, HC, and NO, to limit the discharge of the gas waste. These methods fail to treat the major issue in the engine combustion, the fuel oil. Specifically, the current gas waste treatment method only deals with engine discharges. It has a negative impact on the engine's performance, and cannot improve the fuel efficiency. Thus, it cannot save energy, reduce gas waste gas, and reduce hazardous gases from the root.

### SUMMARY OF THE INVENTION

The goal of the present invention is to provide a permanently magnetic platinum group metal catalyst, which can provide catalysis to the fuel prior to entering the engine, so as to improve the combustion of the fuel in the engine, and improve the engine power output. It also provides an engine fuel enhancer made from this catalyst.

The present invention is achieved through the following technical solution.

The manufacturing process of a magnetic platinum catalyst of the present invention is as follows:

Use powder metallurgy to make a neutral neodymium magnet alloy as a catalyst carrier. The neutral neodymium magnet alloy contains about 25-50% neodymium.

Make a cylinder with a diameter of about 13 mm and a length of about 9 mm from the neutral neodymium magnet alloy as the catalyst carrier. Treat the catalyst carrier surface with antioxidant.

Use platinum group rare earth material as a catalyst to produce a catalyst acid soaking solution. The solution includes about 0.01-0.2% platinum and about 0.01-0.15% rhodium. The pH of the solution is adjusted to 4 using oxalic acid.

Soak the catalyst carrier in the soaking solution for 12-24 hours. After draining and drying, place it into a muffle furnace, and bake it at 300-600° C. Thus, the catalyst is firmly attached to the surface of the carrier to form a magnetic platinum catalyst with catalyzing ability.

Electro-plating is applied on the surface of the magnetic platinum catalyst. Specifically, there are three electro plating layers of nickel, copper, and nickel. Each electro plating layer is about 0.006-0.01 mm thick.

The electro-plated magnetic platinum catalyst is magnetized using a magnetizer. The magnetic flux used in the magnetization is about 3500-5000 Gauss per square centimeter. This forms a magnetic platinum catalyst that has a strong energy flux of catalyzing power and can greatly catalyze the fuel oil to enhance its power.

An engine fuel oil energy enhancer can be made from the magnetic platinum catalyst of the present invention. The engine fuel oil energy enhancer's shell is made of heat-bearing and corrosion-bearing polytetra fluoroethylene material. It has a chamber inside, whose diameter is 13.2 mm. The chamber contains the magnetic platinum catalyst. The cover of the chamber may have a brand logo on it. The magnetic platinum catalyst, a functional circuit board, and cover are placed into the shell in this specified order to form an unit of the engine fuel enhancer. By locking two units of the engine fuel oil energy enhancer to each other to form a duplex, with the north magnetic (N) pole of one unit facing the south magnetic (S) pole of the other unit, an engine fuel enhancer is manufactured.

The two shells of the engine fuel oil energy enhancer are designed to lock to each other. On one side of each shell, there are two locking teeth that are opposite to the other and a docking slot. On the other side of the shell is a latch with teeth on the edges. The shells of the two units lock to each other by engaging the teeth on the latches through the docking slot to the other shell's locking teeth.

The functional circuit board consists of a functional circuit and inductance, etc. It forms a self-motivated power conversion circuit and is connected to a power drainage circuit. This circuit has the ability to drain external power. It is attached to the magnetic platinum catalyst and installed into the chamber. When there is extra static or external electricity accumulation, it can drain the power away.

This engine fuel oil energy enhancer is attached to the oil supply line like a duplex, with the magnetic north (N) pole of one unit facing the magnetic (S) pole of the other. It can then enhance the energy of the fuel oil passing through the oil supply line. This engine fuel oil energy enhancer can also be placed into the oil tank to enhance the energy of the fuel oil.

Through the movement of the earth's crust, mother nature has given extra power to the platinum group metals. They are constantly radiating this power. The energy enhancement of the engine fuel enhancer to the fuel oil is indeed catalyzing the fuel oil by introducing the special energy in the platinum metal into the fuel oil through the magnet particle flux. The catalyzing power of the platinum metals will motivate the oil electrons in the molecule valence zone to transit to a higher zone. The inter-zone electric flow caused by this electron transit makes the oil molecules more active and generates more oxygen negative ions and hydro-oxy free radicals. This improves the degradation of organic and inorganic chemicals, thus improves the combustion efficiency of the engine fuel oil. Eventually, improved fuel oil combustion efficiency makes cleaner combustion of the fuel oil, less hazardous gases like CO, HC, and NO are generated, and more power is produced. In addition, because the fuel oil is catalyzed to have more power, the accumulated carbon in the engine (the unburned colloid attached to the inner wall of the engine) will be oxidized to combustion. It cleanses the cylinder and protects it, and improves power output. The present invention's ability to save energy, reduce discharge, and reduce waste is mainly achieved by making the hard-to-combust portion of the fuel oil burn more thoroughly. Thus less waste and hazardous gases are produced, more power is generated, more mile-per-gallon ratio is achieved, and the energy consumption and waste discharge per mile is reduced.

In summary, the present invention can significantly reduce fuel use, improve the power output of the engine, significantly reduce the discharge of hazardous gases in engine gas waste, to save energy, reduce discharge, and reduce waste. Through several years of experiments and development, and using neodymium permanent magnetic material as carrier and platinum family rare earth metal catalyst as core, the engine fuel enhancer technology has matured. The engine fuel enhancer of the present invention is attached to the oil supply pipeline as a duplex (N pole faces S pole). It has a good impact in catalyzing the fuel oil that passes through the oil supply pipeline to get more energy. The engine fuel enhancer of the present invention has a stable performance, a long life span, and is safe to use.

### BRIEF DESCRIPTION OF THE DRAWINGS

Preferred embodiments of the present invention have been chosen for purposes of illustration and description and are shown in the accompanying drawings forming a part of the specification wherein:

FIG. 1 is an exploded view of an engine fuel enhancer of the present invention.

FIG. 2 is an engine fuel enhancer of the present invention.

FIG. 3 shows the engine fuel oil energy enhancer attached to the oil supply line to produce catalytic effect to the fuel in the pipeline.

FIGS. 4 and 5 are the laboratory testing results of gas waste emission for two gas-empowered automobiles under a stable load.

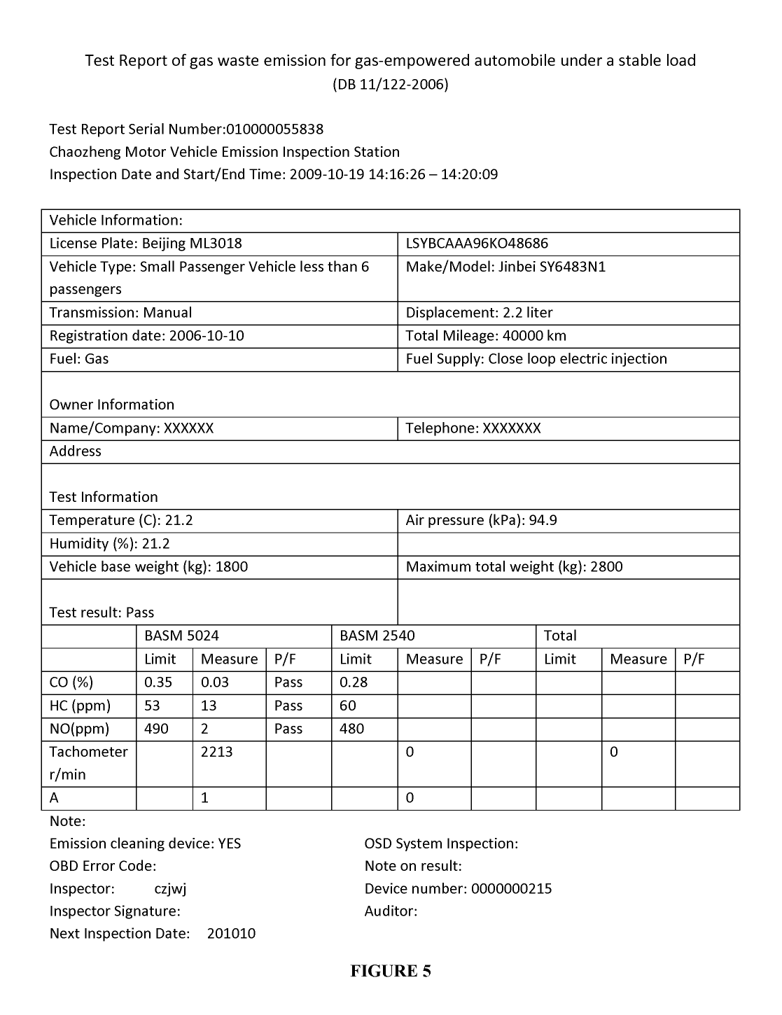

### DETAILED DESCRIPTION OF THE PREFERRED EMBODIMENTS

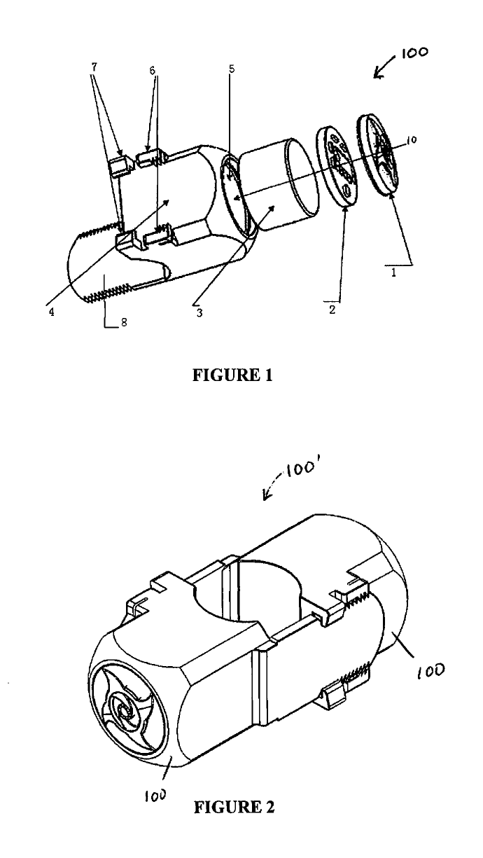

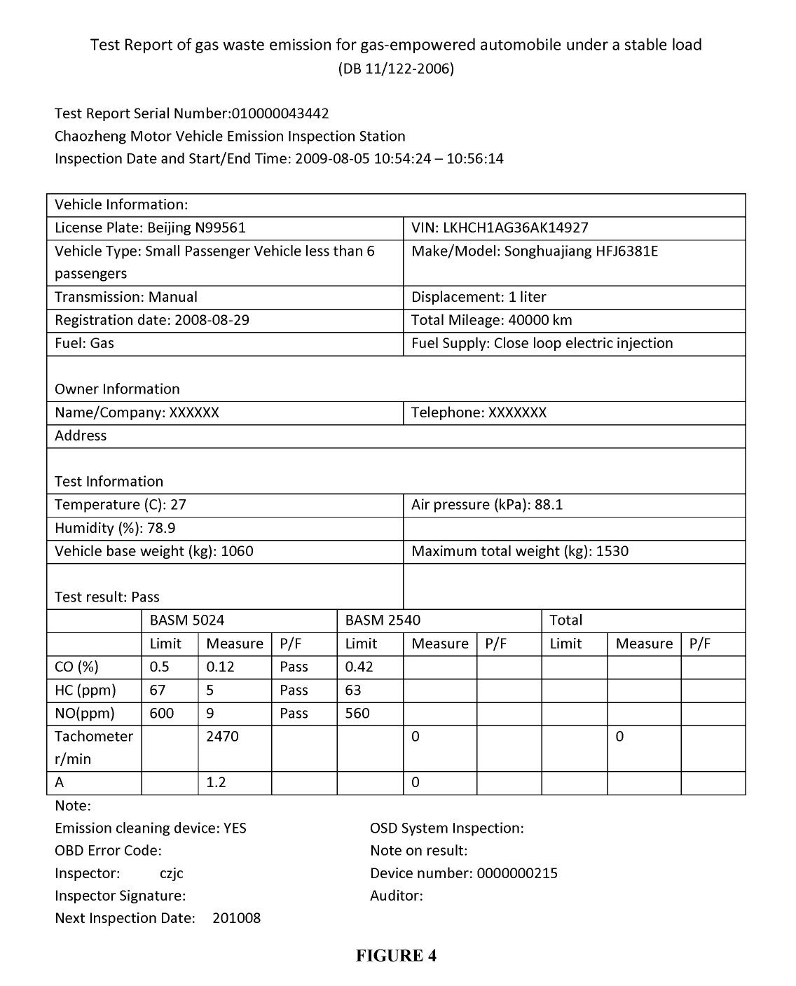

With reference to the drawings, wherein the same reference number indicates the same element throughout, there is shown in FIGS. 1-3 an engine fuel enhancer 100 of the present invention. The reference numbers in the figures correspond to the following elements: cover 1, functional circuit board 2, magnetic platinum catalyst 3, shell 4, chamber 5, locking teeth 6, docking slot 7, latch with teeth 8, fuel supply line 9, and direction of installation 10.

One of the manufacturing methods of the magnetic platinum catalyst is as follow:

Dissolve 6 grams of H₂PtCl₆(H₂PtCl₆.6H₂0) and 4 grams of RhCl₃(RhCl₃.3H₂0) into 1000 ml of water. Use oxalic acid to adjust the pH to 4. Settle for 2 hours. Stir for 10 minutes. Heat to 70° C. This is the platinum group metal catalyst acid soaking solution.

Use powder metallurgy to produce a neutral neodymium magnet alloy. It contains about 39% neodymium. Make it into a cylinder with a diameter of about 13 mm and a length of about 9 mm. This is the catalyst carrier.

Soak the catalyst carrier in the soaking solution for 15 hours. After draining, place it into an oven to bake for 20 minutes. The baking temperature is 75-80° C. This dried carrier is the main body of the magnetic platinum catalyst.

Cool down the body of the platinum catalyst naturally to room temperature. Place it into a muffle furnace to bake for 3 hours. The furnace temperature is 390° C. Cut down the power and wait for the temperature to cool down to below 50° C. Place the baked body into an enclosed, dry, container for future use.

Apply electro-plating to the outer surface of the baked platinum catalyst. Apply three electro plating layers of nickel, copper, and nickel. Each electro-plating layer is about 0.006-0.01 mm thick.

Magnetize the platinum catalyst using a magnetizer after electro-plating is applied.

A magnetic platinum catalyst is manufactured.

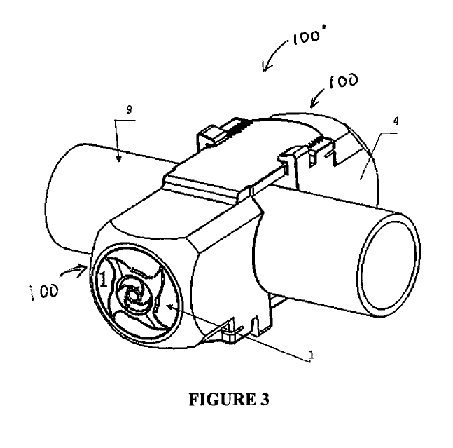

FIGS. 1 and 2 are the exploded and assembled views of the engine fuel enhancer 100. The magnetic platinum catalyst made using the abovementioned method is used to make the engine fuel enhancer 100. The shell 4 of the engine fuel enhancer 100 is made from a heat-bearing and corrosion-bearing polytetra fluoroethylene material. It has a chamber 5 inside with a diameter of 13.2 mm. The chamber 5 contains the magnetic platinum catalyst 3. On the outermost side of the chamber 5 is a cover 1 with a brand logo. The magnetic platinum catalyst 3, a functional circuit board 2, and a cover 1 are placed into the shell 4 in this specified order to form a unit of the engine fuel enhancer 100. By locking two units of the engine fuel enhancer 100 to each other to form a duplex, with the magnetic north (N) pole of one unit facing the magnetic south (S) pole of the other unit, an engine fuel enhancer 100′ is ready for use.

The two shells 4 of the engine fuel enhancer 100′ are designed to lock into each other. On one side of each shell 4, there are two locking teeth 6 that are opposite to each other, with a docking slot 7. On the other side of the shell 4 there is a latch 8 with teeth on the edge. The shells 4 of the two units lock into each other by locking the latch 8 into the other shell's locking teeth 6. By facing the magnetic north (N) pole against the magnetic south (S) pole of the engine fuel enhancer 100, it is fixed onto the oil supply pipeline 9 as a duplex, thus achieving the empowerment and catalyst effect on the fuel that passes through the empowerment/catalyst fuel supply pipeline.

As described above, the engine fuel enhancer 100 is made from special energy material. It continuously emits and outputs energy. To protect its safety and functionality, multiple coatings are applied. To enhance its power, it is magnetized with magnetic power. Magnetic force is also a particle flow. It has the ability to penetrate and carry energy. The stability, dependability, and the ability to empower, activate, and catalyze material (fuel) of the engine fuel enhancer 100 is certainly without any doubt.

The shell 4 of the engine fuel enhancer 100 is made from the best plastic material. Its locking mechanism does not require any accessories, thus it is very safe. The internal functional circuit can completely prevent the buildup of static and interference of outside electricity. Its gross weight is less than 60 grams so the inertia will not hurt or detrimentally affect the pipeline. These are unprecedented in all existing products.

The key of the fuel's combustion in the engine is the quality of the engine. Some automobile engines' ignition, fuel/air mixing, injection, and close-loop fuel control can achieve very high levels of fuel combustion. Some automobiles that meet the Euro 3 standard can achieve a carbon monoxide discharge of less than one per thousand, with the standard being five per thousand. But some or most of the engines cannot achieve this goal. To make the fuel burn better, other than the quality of the engine, processing (activating and catalyzing) the fuel is very important too. The engine fuel enhancer 100 can help in this field. The empowerment to the fuel by the engine fuel enhancer 100 is the catalytic process of special energy to the fuel molecules. The catalyzing power of the platinum metals will motivate the oil electrons in the molecule valence zone to transit to a higher zone. The inter-zone electric flow caused by this electron transit makes the oil molecules more active and generates more oxygen negative ions and hydro-oxy free radicals. This improves the degradation of organic and inorganic chemicals, thus improves the combustion efficiency of the engine fuel oil. Eventually, improved fuel oil combustion efficiency makes cleaner combustion of the fuel oil, and more power is produced. The so called “fuel efficiency” comes from the better combustion of less combusted fuel. Same amount of fuel will produce more mileage. The energy in the fuel is fixed. The fuel efficiency lies in the combustion quality of the fuel in the engine. If the gas can be combusted completely, the final product will only be carbon dioxide and water. If the combustion is not complete, hazardous gases such as carbon monoxide (CO), carbon hydrogen (CH), and nitro-oxide (NO) will be produced. The emission of the hazardous gases can be used to judge the combustion efficiency of the fuel in the engine, and can thus be used to judge fuel efficiency. If the emission of hazardous gases is 0, that means the engine had a complete combustion. All in all, the engine fuel enhancer 100 is an advanced and safe product with great economic value and social value.

The following two tables support the effectiveness of the engine fuel enhancer 100 of the present invention.

Fuel efficiency test results with the engine fuel enhancer 100 installed—Table 1.

License plate: Beijing N995**. Make/Model: Jinbei HEJ6371E. Engine displacement: 1 liter. Fuel: Gas.

Fuel supply type: Close-loop electric injection. Transmission: Manual. Total Mileage: 61809 km.

In the two months before the engine fuel enhancer 100 was installed, the average fuel consumption was 8.2 liter per 100 km.

| Gas | | Mileage | Gas con- | | |
|---|---|---|---|---|---|
| pumping | Total | this | sumption | Liter per | |
| date | Mileage | time | this time | 100 km | Note |
| 08/09/2009 | | | | | Add enhancer 100 |
| 08/11/2009 | 48693 | | 29.8 | | |
| 08/15/2009 | 49112 | 419 | 25.2 | 6 | |
| 08/17/2009 | 49529 | 417 | 33.5 | 8 | |
| 08/21/2009 | 50066 | 427 | 25 | 4.7 | |
| 08/22/2009 | 50457 | 391 | 25.4 | 6.5 | |
| 08/25/2009 | 51216 | 759 | 23.4 | 3.1 | |
| 08/27/2009 | 51589 | 373 | 23.4 | 6.3 | |
| 08/30/2009 | 52206 | 617 | 31.5 | 5.1 | |
| 09/02/2009 | 52640 | 434 | 23.4 | 5.4 | |
| 09/04/2009 | 53100 | 460 | 24.6 | 5.3 | |
| 09/05/2009 | 53434 | 334 | 23.4 | 7 | |
| 09/06/2009 | 53744 | 310 | 21.5 | 6.9 | |
| 09/08/2009 | 54157 | 413 | 28.3 | 6.9 | |
| 09/11/2009 | 54576 | 419 | 27.6 | 6.7 | |
| 09/12/2009 | 55009 | 433 | 24.8 | 5.7 | |
| 09/14/2009 | 55371 | 362 | 20.5 | 5.7 | |
| 09/15/2009 | 55714 | 343 | 25.2 | 7.3 | |
| 09/18/2009 | 56153 | 439 | 25.7 | 5.9 | |
| 09/20/2009 | 56609 | 456 | 25.8 | 5.7 | |
| 09/22/2009 | 57008 | 399 | 25.8 | 6.5 | |
| 09/24/2009 | 57451 | 443 | 28 | 6.3 | |
| 09/26/2009 | 57892 | 441 | 22.4 | 5.1 | |
| 09/28/2009 | 58307 | 415 | 25.8 | 6.2 | |
| 10/02/2009 | 58738 | 431 | 29 | 6.7 | |
| 10/05/2009 | 59087 | 349 | 23.6 | 6.8 | |
| 10/07/2009 | 59521 | 434 | 26.4 | 6.1 | |
| 10/09/2009 | 59951 | 430 | 18.1 | 4.2 | |
| 10/11/2009 | 60129 | 178 | 21.3 | 12 | |
| 10/12/2009 | 60549 | 420 | 24.1 | 5.7 | |
| 10/14/2009 | 61022 | 473 | 27.5 | 5.8 | |
| 10/16/2009 | 61366 | 344 | 29.8 | 8.7 | |
| 10/19/2009 | 61809 | 442 | 26.4 | 6 | |

| | |
|---|---|
| Note | Mileages are actual readings |

| | |
|---|---|
| Average | 6.27 |
| Improvement on fuel efficiency | 23.5% |

Fuel efficiency test results with the engine fuel enhancer 100 installed—Table 2.

License plate: Beijing ML30**. Make/model: Jinbei SY6483N. Displacement: 2.2 liter. Fuel: Gas.

Fuel supply: Close-loop electric injection. Transmission: Manual. Total Mileage:

27916 km. Before installing engine fuel enhancer 100, the record was 10960 km and the average fuel mileage: 12.5 liter per 100 km.

| | | | Gas | | |
|---|---|---|---|---|---|
| Gas pumping | Total | Mileage this | consumption | Liter per | |
| date | Mileage | time | this time | 100 km | Note |
| 04/18/2009 | 10960 | 440 | 44 | 10 | |
| 04/25/2009 | 11431 | 471 | 47 | 10 | |
| 05/01/2009 | 11943 | 521 | 48.6 | 9.3 | |
| 05/06/2009 | 12380 | 437 | 50 | 11.4 | |
| 05/11/2009 | 12936 | 556 | 43.4 | 7.8 | |
| 05/16/2009 | 13371 | 435 | 45.2 | 10.4 | |
| 05/19/2009 | 13921 | 550 | 47.5 | 9.4 | |
| 05/23/2009 | 14296 | 375 | 37.8 | 10 | |
| 05/27/2009 | 14796 | 500 | 49.6 | 9.9 | |
| 06/01/2009 | 15284 | 488 | 42.8 | 8.8 | |
| 06/07/2009 | 15668 | 384 | 44 | 11 | |
| 06/09/2009 | 16105 | 437 | 43 | 9.8 | |
| 06/15/2009 | 16563 | 458 | 43 | 9.4 | |
| 06/22/2009 | 17106 | 543 | 51.7 | 9.5 | |
| 06/26/2009 | 17594 | 488 | 46.6 | 9.6 | |
| 07/03/2009 | 17967 | 373 | 37 | 9.9 | |
| 07/11/2009 | 18434 | 467 | 44.5 | 9.5 | |
| 07/17/2009 | 18877 | 443 | 47.7 | 10.8 | |
| 07/23/2009 | 19327 | 450 | 42.8 | 9.5 | |
| 07/28/2009 | 19800 | 473 | 44.1 | 9.3 | |
| 08/04/2009 | 20286 | 486 | 49.2 | 10.1 | |
| 08/10/2009 | 20814 | 528 | 50.5 | 9.6 | |
| 08/15/2009 | 21316 | 502 | 45.3 | 9.0 | |
| 08/18/2009 | 21721 | 405 | 40.3 | 10 | |
| 08/22/2009 | 22230 | 509 | 44.8 | 8.8 | |
| 08/28/2009 | 22684 | 454 | 51.7 | 11.3 | |
| 09/01/2009 | 23680 | 996 | 90.8 | 9.1 | |
| 09/06/2009 | 24170 | 490 | 41.4 | 8.4 | |
| 09/11/2009 | 24659 | 489 | 49.1 | 10 | |
| 09/14/2009 | 25133 | 474 | 42.3 | 8.9 | |
| 09/17/2009 | 25600 | 467 | 45.8 | 9.8 | |
| 09/21/2009 | 25955 | 355 | 35.5 | 10 | |
| 09/29/2009 | 26492 | 537 | 50 | 9.3 | |
| 10/08/2009 | 26963 | 471 | 49.9 | 10.6 | |
| 10/14/2009 | 27488 | 525 | 49 | 9.3 | |
| 10/18/2009 | 27916 | 428 | 41 | 9.6 | |

| | |
|---|---|
| Note | Mileages are actual readings |

| | |
|---|---|
| Average | 9.7 |
| Improvement on fuel efficiency | 22.4% |

The features of the invention illustrated and described herein are the preferred embodiments. Therefore, it is understood that the appended claims are intended to cover the variations disclosed and unforeseeable embodiments with insubstantial differences that are within the spirit of the claims.

What we claim is:

1. A method of making a magnetic platinum catalyst comprising the steps of:
a. using powder metallurgy to form a neutral neodymium magnetic alloy containing about 25-50% neodymium into a catalyst carrier;
b. making said catalyst carrier into a cylinder with a diameter of about 13 mm and a length of about 9 mm, said catalyst carrier having a surface;
c. treating said surface of said catalyst carrier with an antioxidant;
d. producing a catalyst acid soaking solution with about 0.01-0.2% platinum and about 0.01-0.15% rhodium;
e. adjusting the pH of said solution to 4 with oxalic acid;
f. soaking said catalyst carrier in said solution for 12-24 hours;
g. draining said catalyst carrier from said solution;
h. drying said catalyst carrier;
i. baking said catalyst carrier in a muffle furnace at about 300-600° C. to firmly attach said catalyst onto said surface of said catalyst carrier.

2. The method of claim 1 further comprising the step of electro-plating said surface of said catalyst carrier with a layer of nickel, a layer of copper and another layer of nickel, wherein each said electro-plating layer is about 0.006-0.01 mm thick.

3. The method of claim 1 further comprising the step of magnetizing said catalyst carrier using a magnetizer with a magnetic flux of about 3500-5000 Gauss per square centimeter to form a magnetic platinum catalyst having a strong energy flux of catalyzing power.

4. A method of making a magnetic platinum catalyst having a body, comprising the steps of:
a. making a catalyst acid soaking solution comprises the steps of:
i. dissolving 6 grams of H₂PtCl₆(H₂PtCl₆.6H₂0) and 4 grams of RhCl₃(RhCl₃.3H₂0) into 1000 ml of water;
ii. adjusting the pH of said solution to 4 with oxalic acid;
iii. allowing said solution to settle for about 2 hours;
iv. stirring said solution for about 10 minutes;
v. heating said solution to about 70° C.;
b. making a catalyst carrier comprises the steps of:
i. using powder metallurgy to form a neutral neodymium magnetic alloy containing about 39% neodymium into a catalyst carrier;
ii. making said catalyst carrier into a cylinder with a diameter of about 13 mm and a length of about 9 mm;
c. making the body for the magnetic platinum catalyst having a surface, comprises the steps of:
i. soaking said catalyst carrier in said catalyst acid soaking solution for 15 hours;
ii. draining said catalyst carrier from said solution;
iii. baking said catalyst carrier in an oven for about 20 minutes at a temperature of about 75-80° C.;
d. cooling said body to room temperature;
e. baking said body in a muffle furnace for 3 hours at a temperature of about 390° C.;
f. turning off the muffle furnace and waiting for the temperature to cool down to below 50° C.;
g. removing said body from said muffle furnace;
h. electro-plating the surface of said body with a layer of nickel, a layer of copper and another layer of nickel, wherein each said electro-plating layer is about 0.006-0.01 mm thick;
i. magnetizing said body using a magnetizer.

5. An engine fuel enhancer comprising:
a. at least one shell made of a heat-bearing and corrosion-bearing polytetra fluoroethylene material;
b. least one magnetic platinum catalyst produced according to the method of claim 1; and
c. a chamber inside each said shell having a diameter of about 13.2 mm for receiving said magnetic platinum catalyst.

6. The engine fuel enhancer of claim 5 further comprising at least one functional circuit board and at least one cover, wherein each said circuit board is placed over and attached to each said magnetic platinum catalyst in each said chamber with each said cover enclosing said magnetic platinum catalyst and said circuit board in said chamber of each said shell.

7. The engine fuel enhancer of claim 6 comprises first and second shells locked to each other, each shell having a north magnetic pole, a south magnetic pole and first and second sides, on said first side of each shell are a pair of locking teeth and a docking slot, and on said second side of each shell is a latch with corresponding teeth;
wherein said latch of said first shell engages said locking teeth of said second shell via said docking slot of said second shell, and said latch of said second shell engages said locking teeth of said first shell via said docking slot of said first shell; and
wherein said north magnetic pole of said first shell faces said south magnetic pole of said second shell.

8. The engine fuel enhancer of claim 6 wherein said functional circuit board having means to drain external power comprises a functional circuit, an inductance and a power drainage circuit to form a self-motivated power conversion circuit.

9. A method of enhancing the fuel efficiency of an engine having a fuel line comprising the steps of:
a. providing an engine fuel enhancer of claim 7; and
b. sandwiching said fuel line of said engine between said first and second shells.

10. A method of enhancing the fuel efficiency of an engine having a fuel tank comprising the steps of:
a. providing an engine fuel enhancer of claim 5; and
b. placing said engine fuel enhancer into said fuel tank.

11. A method of making a magnetic platinum catalyst comprising the steps of:
a. making a catalyst acid soaking solution with platinum and rhodium;
b. adjusting the pH of said solution to 4 with oxalic acid;
c. making a catalyst carrier with a neutral neodymium magnetic alloy containing about 25-50% neodymium;
d. treating said catalyst carrier with an antioxidant;
e. soaking said catalyst carrier in said catalyst acid soaking solution;
f. baking said catalyst carrier in a muffle furnace at about 300-600° C.;
g. magnetizing said catalyst with a magnetizer.

12. An engine fuel enhancer comprising:
a. at least one shell made of a heat-bearing and corrosion-bearing material;
b. at least one magnetic platinum catalyst produced according to the method of claim 11; and
c. a chamber inside each said shell for receiving each said magnetic platinum catalyst.
